(19) United States
(12) Patent Application Publication
(10) Pub. No.: US 2009/0268505 A1
(43) Pub. Date: Oct. 29, 2009

(54) Method of Operating an Integrated Circuit, and Integrated Circuit

(76) Inventor: Peter Beer, Weilheim (DE)

Correspondence Address: SLATER & MATSIL, L.L.P., 17950 PRESTON ROAD, SUITE 1000, DALLAS, TX, 75252, US

(21) Appl. No.: 12/108,377

(22) Filed: Apr. 23, 2008

(51) Int. Cl. G11C 11/00

(52) U.S. Cl. 365/148; 365/158; 365/163

(57) ABSTRACT

According to one embodiment of the present invention, a method of operating an integrated circuit including a plurality of resistivity changing memory cells connected in parallel is provided. The method includes: choosing a resistivity changing memory cell having a first memory state out of the plurality of resistivity changing memory cells; measuring a first total resistance of the plurality of resistivity changing memory cells; setting the chosen resistivity changing memory cell to a second memory state, measuring a second total resistance of the plurality of resistivity changing memory cells; and determining the first memory state of the chosen resistivity changing memory cell in dependence on the first total resistance and the second total resistance.

### BACKGROUND

Integrated circuits including resistivity changing memory cells are known. It is desirable to further increase the memory depth of such integrated circuits.

### SUMMARY OF THE INVENTION

According to an embodiment of the present invention, a method of operating an integrated circuit including a plurality of resistivity changing memory cells connected in parallel is provided. The method includes: choosing a resistivity changing memory cell having a first memory state out of the plurality of resistivity changing memory cells; measuring a first total resistance of the plurality of resistivity changing memory cells; setting the chosen resistivity changing memory cell to a second memory state; measuring a second total resistance of the plurality of resistivity changing memory cells; determining the first memory state of the chosen resistivity changing memory cell in dependence on the first total resistance and the second total resistance.

According to an embodiment of the present invention, an integrated circuit is provided including a plurality of resistivity changing memory cells respectively including a current path input terminal and a current path output terminal; a first signal line; a second signal line; a common select device; and a memory state detection unit; wherein the current path input terminals are connected to the first signal line; wherein the current path output terminals are connected to the second signal line via the common select device; and wherein the memory state detection unit is connected to the first signal line and the second signal line, and is configured to apply memory state sensing signals to the resistivity changing memory cells using the first signal line and the second signal line as memory state sensing signal suppliers.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a cross-sectional view of a solid electrolyte memory cell usable as part of an integrated circuit according to one embodiment of the present invention which has been set to a first switching state;

FIG. 1B shows a cross-sectional view of the solid electrolyte memory cell of FIG. 1A set to a second switching state;

FIG. 2 shows a cross-sectional view of a phase changing memory cell usable as part of an integrated circuit according to one embodiment of the present invention;

FIG. 3A shows a cross-sectional view of a carbon memory cell usable as part of an integrated circuit according to one embodiment of the present invention which has been set to a first switching stage;

FIG. 3B shows a cross-sectional view of the carbon memory cell of FIG. 3A set to a second switching state;

FIG. 4 shows a cross-sectional view of a magneto-resistive memory cell usable as part of an integrated circuit according to one embodiment of the present invention;

FIG. 5 shows a flow chart of a method of operating an integrated circuit according to one embodiment of the present invention;

FIG. 6 shows a schematic drawing of an integrated circuit according to one embodiment of the present invention;

FIG. 7 shows a cross-sectional view of an integrated circuit according to one embodiment of the present invention;

FIG. 8 shows a cross-sectional view of an integrated circuit according to one embodiment of the present invention;

FIG. 9 shows a cross-sectional view of an integrated circuit according to one embodiment of the present invention;

FIG. 10 shows a cross-sectional view of an integrated circuit according to one embodiment of the present invention;

FIG. 11A shows a memory module according to one embodiment of the present invention; and

FIG. 11B shows a memory module according to one embodiment of the present invention.

### DETAILED DESCRIPTION OF ILLUSTRATIVE EMBODIMENTS

Generally, embodiments of the integrated circuit according to the present invention as well as embodiments of the method according to the present invention may use arbitrary types of resistivity changing memory cells. Therefore, in the following description, some possible types of resistivity changing memory cells which may be used will be described.

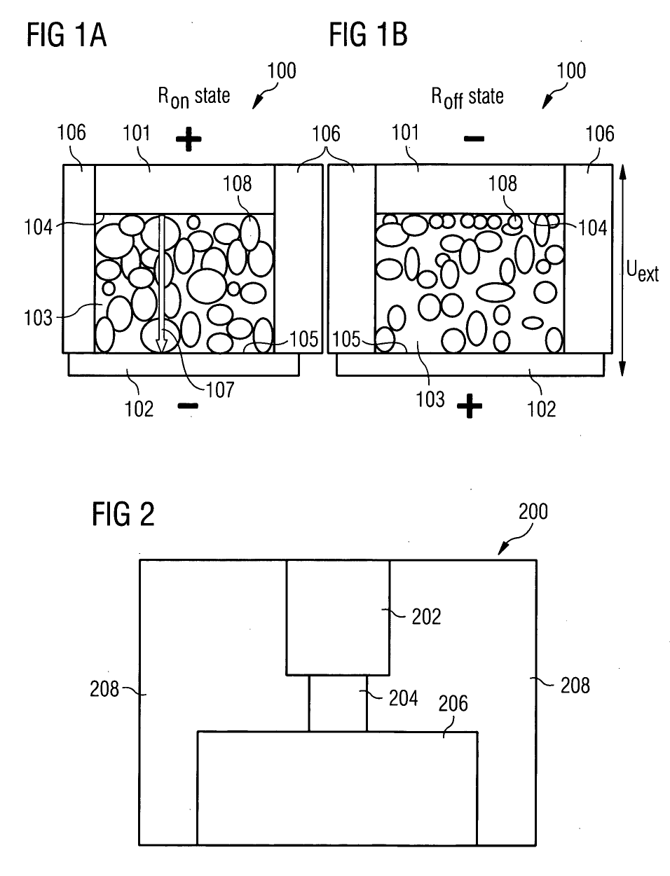

According to one embodiment of the present invention, the resistivity changing memory cells are programmable metallization cells (PMC) (e.g., solid electrolyte memory cells like CBRAM (conductive bridging random access memory) cells). Embodiments of such programmable metallization cells will be described in the following making reference to FIGS. 1A and 1B.

As shown in FIG. 1A, a CBRAM cell 100 includes a first electrode 101, a second electrode 102, and a solid electrolyte block (in the following also referred to as ion conductor block) 103 which includes the active material and which is sandwiched between the first electrode 101 and the second electrode 102. This solid electrolyte block 103 can also be shared between a plurality of memory cells (not shown here). The first electrode 101 contacts a first surface 104 of the ion conductor block 103, the second electrode 102 contacts a second surface 105 of the ion conductor block 103. The ion conductor block 103 is isolated against its environment by an isolation structure 106. The first surface 104 usually is the top surface, the second surface 105 the bottom surface of the ion conductor 103. In the same way, the first electrode 101 generally is the top electrode, and the second electrode 102 the bottom electrode of the CBRAM cell. One of the first electrode 101 and the second electrode 102 is a reactive electrode, the other one an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, the second electrode 102 includes tungsten (W), and the isolation structure 106 includes SiO₂ or Si₃N₄. The present invention is however not restricted to these materials. For example, the first electrode 101 may alternatively or additionally include copper (Cu) or zinc (Zn), and the ion conductor block 103 may alternatively or additionally include copper-doped chalcogenide material. Further, the second electrode 102 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned materials, and can also include alloys of the aforementioned materials. The thickness of the ion conductor 103 may, for example, range between about 5 nm and about 500 nm. The thickness of the first electrode 101 may, for example, range between about 10 nm and about 100 nm. The thickness of the second electrode 102 may, for example, range between about 5 nm and about 500 nm, between about 15 nm to about 150 nm, or between about 25 nm and about 100 nm. It is to be understood that the present invention is not restricted to the above-mentioned materials and thicknesses.

In the context of this description, chalcogenide material (ion conductor) is to be understood, for example, as any compound containing oxygen, sulphur, selenium, germanium and/or tellurium. In accordance with one embodiment of the invention, the ion conducting material is, for example, a compound, which is made of a chalcogenide and at least one metal of the group I or group II of the periodic system, for example, arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage as indicated in FIG. 1A is applied across the ion conductor block 103, a redox reaction is initiated which drives Ag⁺ ions out of the first electrode 101 into the ion conductor block 103 where they are reduced to Ag, thereby forming Ag rich clusters 108 within the ion conductor block 103. If the voltage applied across the ion conductor block 103 is applied for an enhanced period of time, the size and the number of Ag rich clusters within the ion conductor block 103 is increased to such an extent that a conductive bridge 107 between the first electrode 101 and the second electrode 102 is formed. In case that a voltage is applied across the ion conductor 103 as shown in FIG. 1B (inverse voltage compared to the voltage applied in FIG. 1A), a redox reaction is initiated which drives Ag⁺ ions out of the ion conductor block 103 into the first electrode 101 where they are reduced to Ag. As a consequence, the size and the number of Ag rich clusters within the ion conductor block 103 is reduced, thereby erasing the conductive bridge 107. After having applied the voltage/inverse voltage, the memory cell 100 remains within the corresponding defined switching state even if the voltage/inverse voltage has been removed.

A high resistance of the CBRAM cell may, for example, represent “0”, whereas a low resistance represents “1”, or vice versa.

According to one embodiment of the invention, the resistivity changing memory cells are phase changing memory cells that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as a “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase changing material can adopt two crystallization states (an “amorphous state” and a “crystalline state”), however it will be understood that additional intermediate states may also be used.

Phase changing memory cells may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory cell, a sensing current may routed through the phase changing material (or a sensing voltage may be applied across the phase changing material), thereby sensing the resistivity of the resistivity changing memory cell, which represents the memory state of the memory cell. Embodiments of such phase changing memory cells will be described in the following making reference to FIG. 2.

FIG. 2 illustrates a cross-sectional view of an exemplary phase changing memory cell 200 (active-in-via type). The phase changing memory cell 200 includes a first electrode 202, a phase changing material 204, a second electrode 206, and an insulating material 208. The phase changing material 204 is laterally enclosed by the insulating material 208. To set the phase changing material 204 to the crystalline state, a current pulse and/or voltage pulse may be applied to the phase changing material 204, wherein the pulse parameters are chosen such that the phase changing material 204 is heated above its crystallization temperature, while keeping the temperature below the melting temperature of the phase changing material 204. To set the phase changing material 204 to the amorphous state, a current pulse and/or voltage pulse may be applied to the phase changing material 204, wherein the pulse parameters are chosen such that the phase changing material 204 is quickly heated above its melting temperature, and is quickly cooled.

The phase changing material 204 may include a variety of materials. According to one embodiment, the phase changing material 204 may include or consist of a chalcogenide alloy that includes one or more elements from group VI of the periodic table. According to another embodiment, the phase changing material 204 may include or consist of a chalcogenide compound material, such as GeSbTe, SbTe, GeTe or AgInSbTe. According to a further embodiment, the phase changing material 202 may include or consist of chalcogen free material, such as GeSb, GaSb, InSb, or GeGaInSb. According to still another embodiment, the phase changing material 202 may include or consist of any suitable material including one or more of the elements Ge, Sb, Te, Ga, Bi, Pb, Sn, Si, P, O, As, In, Se, and S.

According to one embodiment, at least one of the first electrode 202 and the second electrode 206 may include or consist of Ti, V, Cr, Zr, Nb, Mo, Hf, Ta, W, or mixtures or alloys thereof. According to another embodiment, at least one of the first electrode 202 and the second electrode 206 may include or consist of Ti, V, Cr, Zr, Nb, Mo, Hf, Ta, W and two or more elements selected from the group consisting of B, C, N, O, Al, Si, P, S, and/or mixtures and alloys thereof. Examples of such materials include TiCN, TIAlN, TiSiN, W—Al₂O₃ and Cr—Al₂O₃.

Another type of resistivity changing memory cell which may be used in embodiments of integrated circuits according to the present invention may include carbon as a resistivity changing material. Generally, amorphous carbon that is rich is sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In one embodiment, a carbon memory cell may be formed in a manner similar to that described above with reference to phase changing memory cells. A temperature-induced change between an sp³-rich state and an sp²-rich state may be used to change the resistivity of an amorphous carbon material. These differing resistivities may be used to represent different memory states. For example, a high resistance sp³-rich state can be used to represent a “0”, and a low resistance sp²-rich state can be used to represent a “1”. It will be understood that intermediate resistance states may be used to represent multiple bits, as discussed above.

Generally, in this type of carbon memory cell, application of a first temperature causes a change of high resistivity sp³-rich amorphous carbon to relatively low resistivity sp²-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

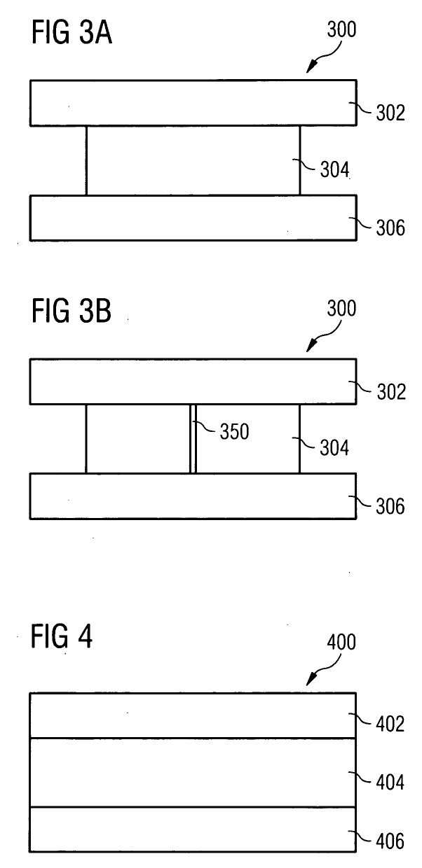

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. Embodiments of such carbon memory cells will be described in the following making reference to FIGS. 3A and 3B.

FIG. 3A shows a carbon memory cell 300 that includes a top contact 302, a carbon storage layer 304 including an insulating amorphous carbon material rich in sp³-hybridized carbon atoms, and a bottom contact 306. As shown in FIG. 3B, by forcing a current (or voltage) through the carbon storage layer 304, an sp² filament 350 can be formed in the sp³-rich carbon storage layer 304, changing the resistivity of the memory cell. Application of a current (or voltage) pulse with higher energy (or, in some embodiments, reversed polarity) may destroy the sp² filament 350, increasing the resistance of the carbon storage layer 304. As discussed above, these changes in the resistance of the carbon storage layer 304 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory cell. In some embodiments, alternating layers of sp³-rich carbon and sp²-rich carbon may be used to enhance the formation of conductive filaments through the sp³-rich layers, reducing the current and/or voltage that may be used to write a value to this type of carbon memory. Another type of resistivity changing memory cells used in integrated circuits according to one embodiment of the present invention may be magneto-resistive memory cells. Magneto-resistive memory cells involve spin electronics, i.e., involve a combination of semiconductor technology and magnetics.

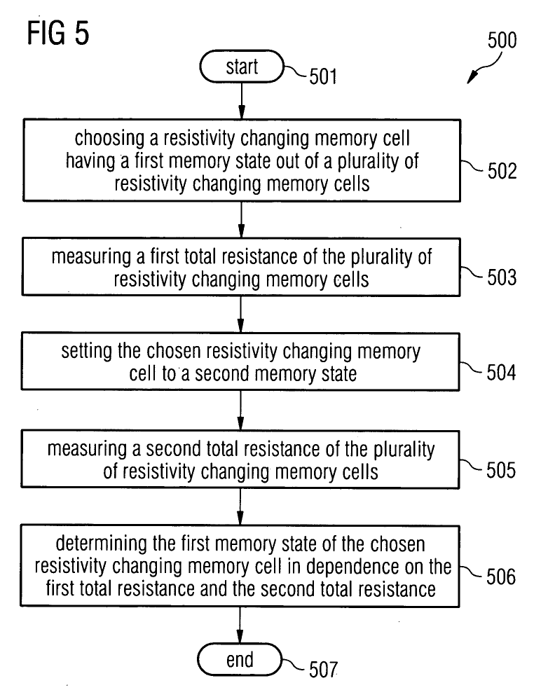

FIG. 4 shows an embodiment of a magneto-resistive memory cell 400 having a soft layer 402, a tunnel layer 404, and a hard layer 406. The soft layer 402 and the hard layer 406 preferably respectively include a plurality of magnetic metal layers, for example, eight to twelve layers of materials such as PtMn, CoFe, Ru, and NiFe, or the like. A logic state is represented by the directions of magnetizations of the soft layer 402 and the hard layer 406.

FIG. 5 shows a method 500 of operating an integrated circuit including a plurality of resistivity changing memory cells connected in parallel. At 501, the method 500 is started. At 502, a resistivity changing memory cell having a first memory state is chosen from the plurality of resistivity changing memory cells. At 503, a first total resistance of the plurality of resistivity changing memory cells is measured. At 504, the chosen resistivity changing memory cell is set to a second memory state. At 505, a second total resistance of the plurality of resistivity changing memory cells is measured. At 506, a first memory state of the chosen resistivity changing memory cell is determined in dependence on the first total resistance and the second total resistance. At 507, the method 500 is terminated.

The method 500 determines the memory state of a particular resistivity changing memory cell chosen out of a plurality of resistivity changing memory cells by measuring the total resistance of the plurality of resistivity changing memory cells. This means that only one common select device which is assigned to all resistivity changing memory cells of the plurality of resistivity changing memory cells is needed in order to determine the memory state of the chosen resistivity changing memory cell; instead of individually selecting the chosen resistivity changing memory cell, it is sufficient to select the plurality of resistivity changing memory cells as a whole. This enables to widely decouple the memory depth of a memory device including resistivity changing memory cells from the size of the select devices assigned to the resistivity changing memory cells.

Further since the chosen resistivity changing memory cell itself is used as reference cell (“self-referencing” memory state detection), no extra reference cells are needed in order to carry out method 500. In order to determine the first memory state (e.g., the current memory state) of the chosen resistivity changing memory cell, the resistance of the chosen resistivity changing memory cell reflecting the first memory state is measured (the resistance of the chosen resistivity changing memory cell is not measured directly, but indirectly by measuring the first total resistance). Then, the resistivity changing memory state is set to the second memory state (i.e., reprogrammed to the first memory state or set to a memory state which differs from the first memory state), and the corresponding resistance reflecting the second memory state is measured (again, the resistance of the chosen resistivity changing memory cell is not measured directly, but indirectly by measuring the second total resistance). By comparing both resistances measured, it is possible to determine the current memory state.

Depending on the design of the memory state detection circuit, two total resistances (reflecting the first memory state and the second memory state) may not be sufficient to determine the first memory state. Therefore, according to one embodiment of the present invention, after having measured the second total resistance of the plurality of resistivity changing memory cells at 505, the selected resistivity changing memory cell is set to a third memory state, and a third total resistance of the plurality of resistivity changing memory cells is measured, wherein, at 506, the first memory state of the selected resistivity changing memory cell is determined in dependence on the first total resistance, the second total resistance, and the third total resistance.

According to one embodiment of the present invention, the first memory state is identical to the second memory state or the third memory state (this may, for example, be the case if the resistivity changing memory cells can adopt two different memory states).

According to one embodiment of the present invention, the first total resistance, the second total resistance, and the third total resistance are respectively measured by simultaneously applying sensing signals to all resistivity changing memory cells. For example, the first total resistance, the second total resistance, and the third total resistance are respectively measured by simultaneously routing sensing currents through all resistivity changing memory cells. Alternatively or additionally, voltage signals may be applied to the resistivity changing memory cells in order to determine their memory states.

If sensing currents are used as sensing signals, all sensing currents may be combined to one total sensing current after having routed the sensing currents through a plurality of resistivity changing memory cells. The memory state of a resistivity changing memory cell chosen out of the plurality of resistivity changing memory cells may then be determined on the basis of the total sensing current. In this way, only one select device is needed in order to sense the memory states of any resistivity changing memory cell chosen out of the plurality of resistivity changing memory cells.

According to one embodiment of the present invention, the resistivity changing memory cells are magneto-resistive memory cells.

According to one embodiment of the present invention, the resistivity changing memory cells are programmable metallization memory cells.

According to one embodiment of the present invention, the resistivity changing memory cells are phase changing memory cells.

According to one embodiment of the present invention, the resistivity changing memory cells are carbon memory cells.

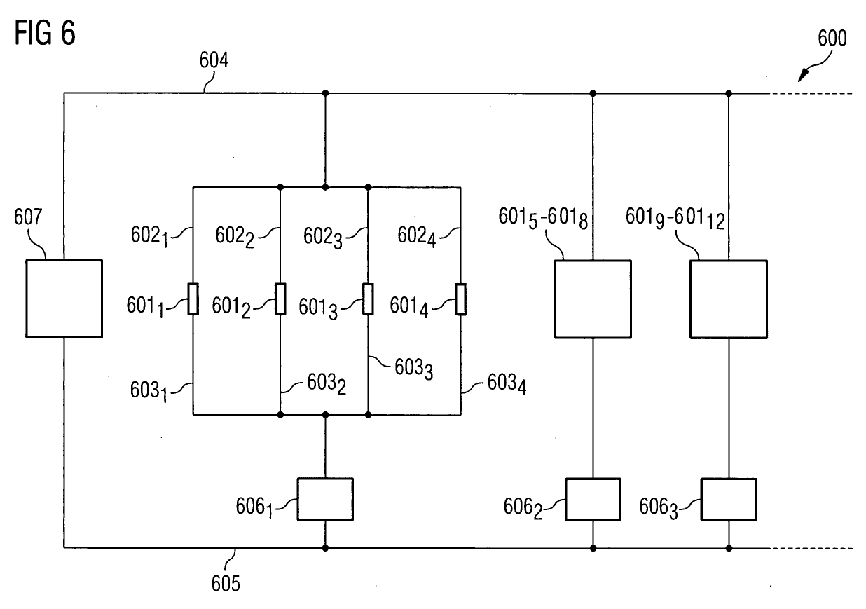

FIG. 6 shows an integrated circuit 600 according to one embodiment of the present invention. The integrated circuit 600 includes a plurality of resistivity changing memory cells 601₁-601₄, collectively 601, which respectively include a current path input terminal 602₁-602₄, collectively 602, and a current path output terminal 603₁-603₄, collectively 603, a first signal line 604, a second signal line 605, a common select device 606₁-606₃, collectively 606, and a memory state detection unit 607. The current path input terminals 602 are connected to the first signal line 604, whereas the current path output terminals 603 are connected to the second signal line 605 via the common select device 606. The memory state detection unit 607 is connected to the first signal line 604 and the second signal line 605, and is configured to apply memory state sensing signals to the resistivity changing memory cells 601 using the first signal line and the second signal line as memory state sensing signal suppliers. The second signal line 605 may be replaced by ground.

In the following, it is assumed that the memory state of the resistivity changing memory cell 601₁ has to be determined. In order to do this, the common select device 606₁ is activated (using corresponding activation lines not shown here), i.e., the common select device 606₁ is switched from a resistive state into a conductive state (it is assumed here that the first signal line 604 and the second signal line 605 are connected to an arbitrary number of further blocks of resistivity changing memory cells which are summarized by reference numerals 601₅ to 601₈ and 601₉ to 601₁₂ in the right part of FIG. 6 and which can be selected using corresponding select devices (which are summarized by reference numerals 606₂ and 606₃)). After having activated the common select device 606₁, a sensing signal is applied by the memory state detection unit 607 to the resistivity changing memory cells 601. For example, a common sensing current is routed via the first signal line 604 to the current path input terminals 602₁ to 602₄. This means that the sensing current is split into four sensing currents which are routed through the resistivity changing memory cells 601₁ to 601₄, and which are re-combined after having passed the corresponding current path output terminals 603₁ to 603₄ into the common sensing current which passes the common select device 606₁ and which flows back to the memory state detection unit 607 via the second signal line 605. In this way, a first total resistance of the resistivity changing memory cells 601₁ to 601₄ is determined. Then, the memory state of the resistivity changing memory cell 601₁ is re-programmed to a memory state which may be the same memory state or a different memory state. The memory states of the resistivity changing memory cells 601₂ to 601₄ are not changed. The re-programming of the memory state of the resistivity changing memory cell 601₁ is done using at least some programming means not shown in FIG. 6. Now, a second total resistance of the resistivity changing memory cells 601₁ to 601₄ is measured in the same way as explained above. If the reprogrammed memory state of the resistivity changing memory cell 601₁ has changed, also the total resistance of the resistivity changing memory cells 601₁ to 601₄ has changed. If the memory state of the resistivity changing memory cell 601₁ has not changed, also the total resistance of the resistivity changing memory cells 601₁ to 601₄ has not changed. Since the reprogrammed memory state of the resistivity changing memory cell 601₁ is known, it can be determined whether the original memory state of the resistivity changing memory cell 601₁ is the same memory state as the reprogrammed memory state or not by comparing corresponding total resistances of the resistivity changing memory cells 601₁ to 601₄ which have been measured before. In this way, the resistivity changing memory cell 601₁ itself is used as reference cell in order to determine its memory state.

One effect of the integrated circuit is that only one common select device 606₁ (but not for different select devices) is needed in order to determine the memory states of the resistivity changing memory cells 601₁ to 601₄.

According to one embodiment of the present invention, the resistivity changing memory cells 601 are magneto-resistive memory cells. However, it is to be understood that the embodiments of the present invention can be applied to arbitrary resistivity changing memory cells. For example, also programmable metallization cells (PMCs), magneto-resistive memory cells (e.g., MRAMs), organic memory cells (e.g., ORAMs), or transition oxide memory cells (TMOs) may be used.

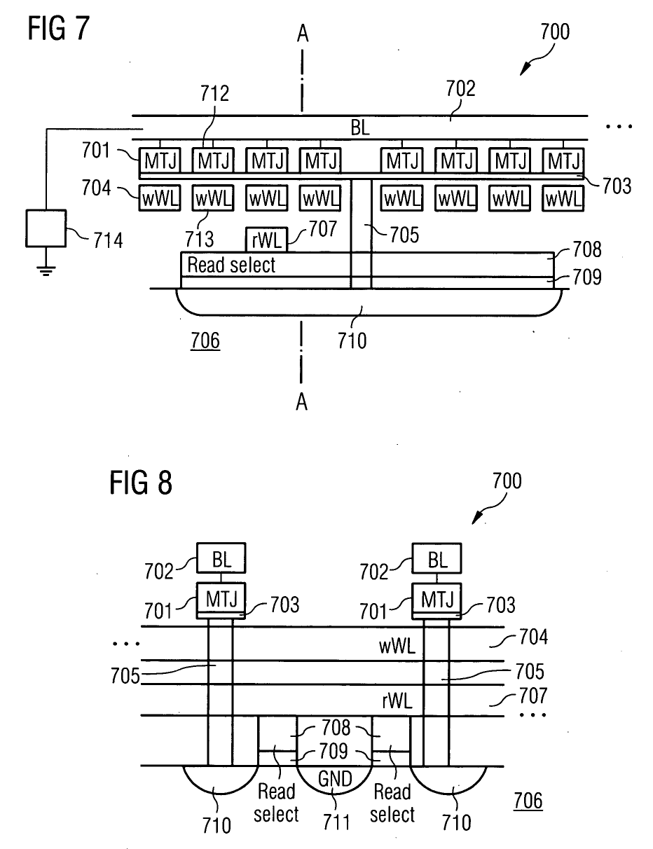

FIG. 7 shows an integrated circuit 700 including a plurality of magneto-resistive memory cells 701, a bit line 702 being connected to current path input terminals of the magneto-resistive memory cells 701, a common conductive element 703 being connected to current path output terminals of the magneto-resistive memory cells 701, a plurality of write word lines 704 which are located below the common conductive element 703 and which extend along a direction being perpendicular to the direction of the bit line 702, and a conductive via 705 connecting the common conducting element 703 to a semiconductor substrate 706. The integrated circuit 700 further includes a read word line 707 which extends along a direction being perpendicular to the direction of the bit line 702. Further, a conductive read/select element 708 and an isolation element 709 provided between the substrate 706 and the conductive read/select element 708 is provided, wherein the read word-line 707 contacts the top surface of the conductive read/select element 708. The substrate 706 includes a source region 710 and a drain region 711, wherein the source region 710 is contacted by the conductive via 705, and wherein the drain region 711 is connected to ground. A conductive channel can be formed within a part of the substrate positioned between the source/drain region 710 using the conductive read/select element 708 as gate electrode and the isolation element 709 as gate electrode isolation layer.

FIG. 8 shows a cross-sectional view of the integrated circuit 700 along a direction indicated by line A in FIG. 7. The connection between the source region 710 and the drain region 711 can be activated and deactivated using the read word line 707 which controls the gate electrode (conductive read/select element 708).

In the integrated circuit 700, eight magneto-resistive memory cells 701 share one common select device (the common select device includes the source area 710, the drain area 711, and the gate electrode 708, and is controlled by the read word line 707).

It is assumed in the following that the memory state of the resistivity changing memory cell denoted by reference numeral 712 has to be determined. In order to do this, the common select device is activated using the read word line 707. The activation of the common select device effects that a sensing current flowing through the bit line 702 splits into eight sensing currents, each sensing current flowing through one of the eight magneto-resistive memory cells 701. The sensing currents are then re-combined within the common conductive element 703 such that a recombined sensing current flows through the conductive via 705 to the source area 710. Due to the activation of the common select device, the area of the substrate 706 between the source area 710 and the drain area 711 is conductive, and the sensing current flows from the source area 710 to the drain area 711 which is connected to ground.

In this way, a memory state detection unit 714 which is connected to the bit line 702 and to ground generates a sensing current as described above. The sensing current reflects the total resistance of the eight magneto-resistive memory cells 701. Then, the magneto-resistive memory cell 712 is re-programmed to a memory state which is either identical to or different from the current memory state. The re-programming is carried out using the write word line denoted by reference numeral 713 which is located below the magneto-resistive memory cell 712 and the bit line 702 (the bit line 702 and the write word line 713 carry write currents which generate a magnetic field causing the memory state of the magneto-resistive memory cell 712 to switch its memory state). Then, the total resistance of the magneto-resistive memory cells 701 is measured again as described above. If the memory state of the magneto-resistive memory cell 712 has changed, there is a corresponding change within the total resistance of the eight magneto-resistive memory cells 701; if it is the same memory state, there is no change within the total resistance. In this way, the memory state of the magneto-resistive memory cell 712 can be measured using a single select device for eight magneto-resistive memory cells 701.

It is to be understood that the present invention is not limited to a particular amount of resistivity changing memory cells connected to the common select device.

The architecture shown in FIG. 7 may be repeated arbitrary times in order to form a memory cell array, as indicated in FIG. 8, along a direction parallel to the write word line, and/or along a direction parallel to the bit line (for example, the bit line 702 may be connected to an arbitrary amount of magneto-resistive memory cells 701 which are grouped together into groups of eight magneto-resistive memory cells, wherein each group of eight magneto-resistive memory cells is connected to ground via a single common select device assigned to the group of magneto-resistive memory cells). Each conductive read/select element 708 is assigned to one group of magneto-resistive memory cells, whereas each write word line 704 and each read word line 707 may be assigned to a plurality of groups of magneto-resistive memory cells.

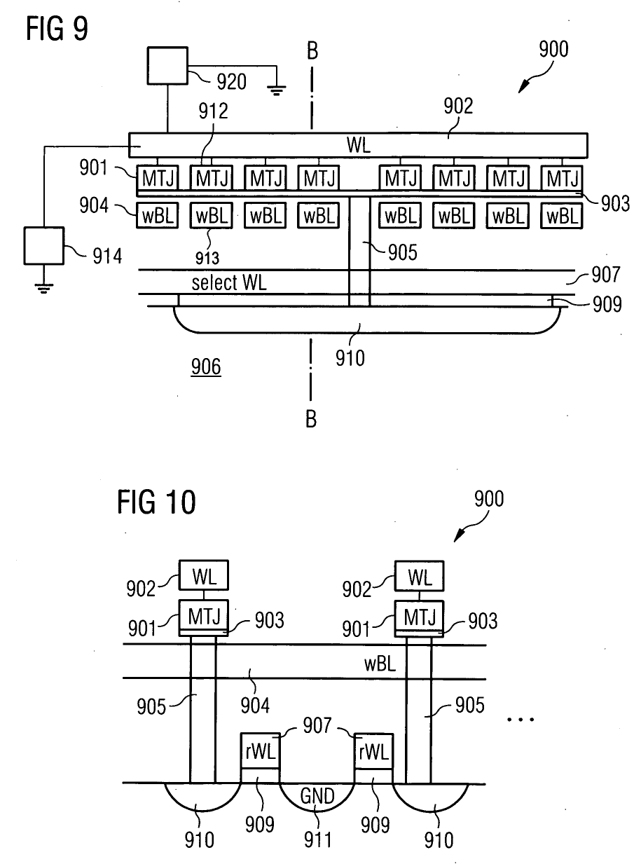

FIG. 9 shows an integrated circuit 900 including a plurality of magneto-resistive memory cells 901, a word line 902 being connected to current path input terminals of the magneto-resistive memory cells 901, a common conductive element 903 being connected to current path output terminals of the magneto-resistive memory cells 901, a plurality of write bit lines 904 which are located below the common conductive element 903 and which extend along a direction being perpendicular to the direction of the word line 902, and a conductive via 905 connecting the common conducting element 903 to a semiconductor substrate 906. The integrated circuit 900 further includes a read word line 907 which extends along a direction being perpendicular to the direction of the word line 902. Further, an isolation element 909 provided between the substrate 906 and the read word line 907 is provided. The substrate 906 includes a source region 910 and a drain region 911, wherein the source region 910 is contacted by the conductive via 905, and wherein the drain region 911 is connected to ground. A conductive channel can be formed within a part of the substrate positioned between the source region 910 and the drain region 911 using the read word line 907 as gate electrode and the isolation element 909 as gate electrode isolation layer. FIG. 10 shows a cross-sectional view of the integrated circuit 900 along a direction indicated by line B in FIG. 9.

In the integrated circuit 900, eight magneto-resistive memory cells 901 share one common select device (the common select device includes the source area 910, the drain area 911, the read word line 907 and the isolation element 909).

It is assumed in the following that the memory state of the resistivity changing memory cell denoted by reference numeral 912 has to be determined. In order to do this, the common select device is activated using the read word line 907. The activation of the common select device effects that a sensing current flowing through the word line 902 splits into eight sensing currents, each sensing current flowing through one of the eight magneto-resistive memory cells 901. The sensing currents are then re-combined within the common conductive element 903 such that a recombined sensing current flows through the conductive via 905 to the source area 910. Due to the activation of the common select device, the area of the substrate 906 between the source area 910 and the drain area 911 is conductive, and the sensing current flows from the source area 910 to the drain area 911 which is connected to ground.

In this way, a memory state detection unit 914 which is connected to the word line 902 and to ground generates a sensing current as described above. The sensing current reflects the total resistance of the eight magneto-resistive memory cells 901. Then, the magneto-resistive memory cell 912 is re-programmed to a memory state which is either identical to or different from the current memory state. The re-programming is carried out using the write bit line denoted by reference numeral 913 which is located below the magneto-resistive memory cell 912 and the word line 902 (the word line 902 and the write bit line 913 carry write currents which generate a magnetic field causing the memory state of the magneto-resistive memory cell 912 to switch its memory state). Then, the total resistance of the magneto-resistive memory cells 901 is measured again as described above. If the memory state of the magneto-resistive memory cell 912 has changed, there is a corresponding change within the total resistance of the eight magneto-resistive memory cells 901; if it is the same memory state, there is no change within the total resistance. In this way, the memory state of the magneto-resistive memory cell 912 can be measured using a single select device for eight magneto-resistive memory cells 901.

It is to be understood that the present invention is not limited to a particular amount of resistivity changing memory cells connected to the common select device.

The architecture shown in FIG. 9 may be repeated arbitrary times in order to form a memory cell array, as indicated in FIG. 10, along a direction parallel to the write word line, and/or along a direction parallel to the bit line (for example, the read word line 907 may be connected to an arbitrary amount of select devices, each select device being connected to one single group of magneto-resistive memory cells). Each word line 902 is assigned to one single group of eight magneto-resistive memory cells, whereas each write bit line 904 may be assigned to a plurality of groups of magneto-resistive memory cells.

Before switching the memory state of the magneto-resistive memory cell 912, all memory cells 901 of a memory cell group are heated by a heating unit 920 which routs a heating current through the memory cells 901 using the word line 902 as the heat current supplier. This means that memory cells 901 of other memory cell groups are not heated.

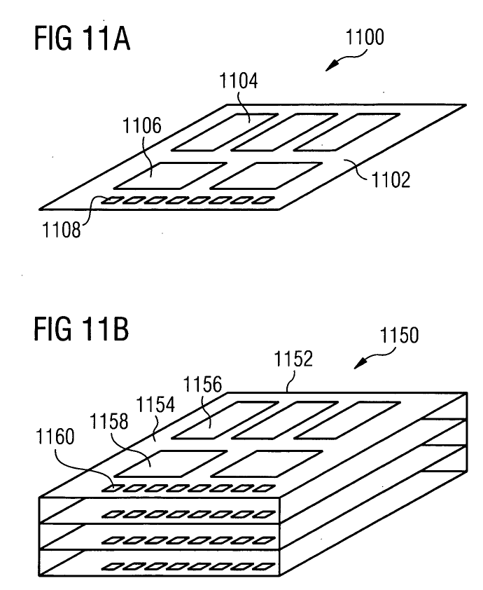

As shown in FIGS. 11A and 11B, in some embodiments, integrated circuits/memory devices such as those described herein may be used in modules. In FIG. 11A, a memory module 1100 is shown, on which one or more integrated circuits/memory devices 1104 are arranged on a substrate 1102. The integrated circuits/memory devices 1104 may include numerous memory cells. The memory module 1100 may also include one or more electronic devices 11 06, which may include memory, processing circuitry, control circuitry, addressing circuitry, bus interconnection circuitry, or other circuitry or electronic devices that may be combined on a module with a memory device, such as the integrated circuits/memory devices 1104. Additionally, the memory module 1100 includes multiple electrical connections 1108, which may be used to connect the memory module 1100 to other electronic components, including other modules.

As shown in FIG. 11B, in some embodiments, these modules may be stackable, to form a stack 1150. For example, a stackable memory module 1152 may contain one or more integrated circuits/memory devices 1156, arranged on a stackable substrate 1154. The integrated circuits/memory devices 1156 contain memory cells. The stackable memory module 1152 may also include one or more electronic devices 1158, which may include memory, processing circuitry, control circuitry, addressing circuitry, bus interconnection circuitry, or other circuitry or electronic devices that may be combined on a module with a memory device, such as the integrated circuits/memory devices 1156. Electrical connections 1160 are used to connect the stackable memory module 1152 with other modules in the stack 1150, or with other electronic devices. Other modules in the stack 1150 may include additional stackable memory modules, similar to the stackable memory module 1152 described above, or other types of stackable modules, such as stackable processing modules, control modules, communication modules, or other modules containing electronic components.

In the following description, further aspects of exemplary embodiments of the present invention will be explained.

High density MRAM arrays with high access performance may need read out select devices. However, read out select devices generally require a lot of area, thus limiting a further scaling down of the MRAM arrays. For example, a 1T1MTJ (one transistor, one magnetic tunnel junction cell) scheme may be used, with the drawback of cell size shrinking limitations. Alternatively, a cross point cell array may be used which however has the drawback of slow access times.

According to one embodiment of the present invention, a plurality of resistive memory cells are connected to the same bit line and to the same select device, and a self referencing read scheme is used. This provides the possibility to reduce the cell size, while at the same time having fast read access times. The only drawback is the reduction of the read sensing signal, which is divided by the number of cells which are connected to one select device (e.g., transistor). However, today magneto resistance values larger than 100% have been shown, while with self referencing read scheme a signal around 5% is sufficient to sense a cell. This ratio gives for example the opportunity to connect up to 16 cells to one read out transistor.

According to one embodiment of the present invention, a plurality of MTJs are connected to the same bit line and the select transistor, while self-referencing read out schemes are used.

FIGS. 7 and 8 show an implementation for a “adiabatic rotation” storage cell according to one embodiment of the present invention: A plurality of memory cells are connected to the same bit line, and via a common conducting plate, to the select device. Self referencing reading may be performed by comparing the cell resistance before and after toggling a cell, selecting one cell out of the many simultaneously selected cells by the right word line address.

FIGS. 9 and 10 show an implementation for a “thermal select” storage cell according to one embodiment of the present invention, using the reference system for the info storage. A plurality of memory cells are connected to the same word line, and via a common conducting plate, to the select device. Self referencing reading may be performed by comparing the cell resistance before and after setting the free layer on all cells connected to the same select device.

Within the scope of the present invention, the terms “connecting” and “coupling” both include direct connecting/coupling and indirect connecting/coupling.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of operating an integrated circuit comprising a plurality of resistivity changing memory cells coupled in parallel, the method comprising:
selecting a resistivity changing memory cell out of the plurality of resistivity changing memory cells, the selected resistivity changing memory cell having a first memory state;
measuring a first total resistance of the plurality of resistivity changing memory cells;
setting the selected resistivity changing memory cell to a second memory state;
measuring a second total resistance of the plurality of resistivity changing memory cells; and
determining the first memory state of the selected resistivity changing memory cell based upon the first total resistance and the second total resistance.

2. The method according to claim 1, further comprising:
setting the selected resistivity changing memory cell to a third memory state after having measured the second total resistance of the plurality of resistivity changing memory cells;
measuring a third total resistance of the plurality of resistivity changing memory cells; and
determining the first memory state of the selected resistivity changing memory cell based upon the first total resistance, the second total resistance, and the third total resistance.

3. The method according to claim 2, wherein the first memory state is identical to the second memory state or the third memory state.

4. The method according to claim 2, wherein the first total resistance, the second total resistance, and the third total resistance are measured by simultaneously applying sensing signals to all resistivity changing memory cells of the plurality of resistivity changing memory cells.

5. The method according to claim 2, wherein the first total resistance, the second total resistance, and the third total resistance are measured by simultaneously routing sensing currents through all resistivity changing memory cells.

6. The method according to claim 5, wherein all sensing currents are combined to one total sensing current after having routed them through the resistivity changing memory cells.

7. The method according to claim 1, wherein the resistivity changing memory cells comprise magneto-resistive memory cells.

8. The method according to claim 1, wherein the resistivity changing memory cells comprise programmable metallization memory cells.

9. The method according to claim 1, wherein the resistivity changing memory cells comprise phase changing memory cells.

10. The method according to claim 1, wherein the resistivity changing memory cells comprise carbon memory cells.

11. An integrated circuit, comprising:
a plurality of resistivity changing memory cells, each memory cell comprising a current path input terminal and a current path output terminal;
a first signal line;
a second signal line;
a common select device; and
a memory state detection unit;
wherein the current path input terminals of each memory cell are coupled to the first signal line;
wherein the current path output terminals of each memory cell are coupled to the second signal line via the common select device; and
wherein the memory state detection unit is coupled to the first signal line and the second signal line, and is configured to apply memory state sensing signals to the resistivity changing memory cells using the first signal line and the second signal line as memory state sensing signal suppliers.

12. The integrated circuit according to claim 11, wherein the resistivity changing memory cells comprise magneto-resistive memory cells.

13. The integrated circuit according to claim 12, wherein the first signal line is a bit line, and wherein the second signal line is coupled to a fixed potential.

14. The integrated circuit according to claim 13, further comprising:
a plurality of write word lines arranged perpendicular to the bit line, wherein an individual write word line is assigned to each resistivity changing memory cell; and
a read word line arranged perpendicular to the bit line and being configured to activate/deactivate the select device.

15. The integrated circuit according to claim 14, further comprising a memory state programming unit that is coupled to the bit line and the write word lines and is configured to program memory states by applying a programming current to the resistivity changing memory cells using the bit line and the write word lines as programming current suppliers.

16. The integrated circuit according to claim 12, wherein the first signal line is a word line, and wherein the second signal line is coupled to a fixed potential.

17. The integrated circuit according to claim 16, further comprising:
a plurality of write bit lines arranged perpendicular to the bit line, wherein an individual write bit line is assigned to each resistivity changing memory cell; and
a read word line arranged in parallel to the word line and configured to activate/deactivate the select device.

18. The integrated circuit according to claim 17, further comprising a memory state programming unit that is coupled to the word line and the write bit lines and is configured to program memory states by applying a programming current to the resistivity changing memory cells using the word line and the write bit lines as programming current suppliers.

19. The integrated circuit according to claim 16, further comprising a heating unit that heats the resistivity changing memory cells by routing a heating current through the resistivity changing memory cells using the first signal line and the second signal line as heating current suppliers.

20. The integrated circuit according to claim 11, wherein the current path output terminals together form one common conductive plate.

21. The integrated circuit according to claim 11, wherein the resistivity changing memory cells comprise programmable metallization memory cells.

22. The integrated circuit according to claim 11, wherein the resistivity changing memory cells comprise phase changing memory cells.

23. The integrated circuit according to claim 11, wherein the resistivity changing memory cells comprise carbon memory cells.

24. The integrated circuit according to claim 11, wherein the plurality of resistivity changing memory cells comprises 2ⁿ memory cells, n comprising an integer between 1 and 4.

25. A memory module comprising at least one integrated circuit,
the integrated circuit comprising a plurality of resistivity changing memory cells comprising a current path input terminal and a current path output terminal, respectively; a first signal line; a second signal line; a common select device; and a memory state detection unit;
wherein the current path input terminals are connected to the first signal line;
wherein the current path output terminals are connected to the second signal line via the common select device; and
wherein the memory state detection unit is connected to the first signal line and the second signal line, and is configured to apply memory state sensing signals to the resistivity changing memory cells using the first signal line and the second signal line as memory state sensing signal suppliers.
